(19) United States
(12) Patent Application Publication
(10) Pub. No.: US 2014/0209150 A1
(43) Pub. Date: Jul. 31, 2014

(54) SOLAR CELL MODULE

(71) Applicants: Panasonic Corporation, Osaka (JP); SANYO ELECTRIC CO., LTD., Osaka (JP)

(72) Inventors: Shuji FUKUMOCHI, Moriguchi-city (JP); Toshiyuki SAKUMA, Moriguchi-city (JP); Takahiro HAGA, Moriguchi-city (JP); Shingo OKAMOTO, Moriguchi-city (JP); Keiichi KURAMOTO, Moriguchi-city (JP); Kenichiro MASE, Kadoma-shi (JP); Yohei TAKECHI, Kadoma-shi (JP)

(73) Assignees: Panasonic Corporation, Osaka (JP); SANYO ELECTRIC CO., LTD., Osaka (JP)

(21) Appl. No.: 14/165,618

(22) Filed: Jan. 28, 2014

(30) Foreign Application Priority Data
Jan. 29, 2013 (JP) 2013-014433

(51) Int. Cl. H01L 31/048

(52) U.S. Cl. CPC H01L 31/0481
USPC 136/251

(57) ABSTRACT

A solar cell module includes solar cells, a wiring member electrically connecting the solar cells, a first protection member provided on a light-receiving-surface side of the solar cells, a second protection member provided on a back-surface side of the solar cells, and a sealing material provided between the first protection member and the second protection member to seal the solar cells therein. The first protection member has a first texture on one of principal surfaces thereof that faces the opposite side of the solar cells. The wiring member has a second texture on one of principal surfaces thereof that faces the first protection member. The first texture and the second texture are provided such that, in a plan view, a normal to a surface of the first texture is not parallel to a normal to a surface of the second texture.

### CROSS REFERENCE TO RELATED APPLICATIONS

This application claims priority based on 35 USC 119 from prior Japanese Patent Application No. 2013-014433 filed on Jan. 29, 2013, ENTITLED “SOLAR CELL MODULE”, the entire contents of which are incorporated herein by reference.

### BACKGROUND OF THE INVENTION

1. Field of the Invention

The disclosure herein relates to a solar cell module.

2. Description of Related Art

In recent years, solar cell modules have been drawing attention as an environmentally-friendly energy source. As described in Japanese Patent Application Publication No. 2012-175065, a solar cell module includes solar cells electrically connected to each other with wiring members, a first protection member placed on a light-receiving-surface side of the solar cells, a second protection member placed at a back-surface side of the solar cells, and a sealing material placed between the first protection member and the second protection member to seal the solar cells therein.

### SUMMARY OF THE INVENTION

There are needs for improvement in the output characteristics of the solar cell modules.

An objective of an embodiment of the invention is to provide a solar cell module with excellent output characteristics.

An aspect of the invention is a solar cell module that comprises: solar cells; a wiring member electrically connecting the solar cells; a first protection member provided on a light-receiving-surface side of the solar cells; a second protection member provided on a back-surface side of the solar cells; and a sealing material provided between the first protection member and the second protection member to seal the solar cells therein. The first protection member has a first texture on one of principal surfaces that faces an opposite direction from the solar cells. The wiring member has a second texture on one of principal surfaces thereof that faces the first protection member. The first texture and the second texture are provided such that, in a plan view, a normal to a surface of the first texture is not parallel to a normal to a surface of the second texture.

According to the above aspect of the invention, a solar cell module with excellent output characteristics can be provided.

### BRIEF DESCRIPTION OF THE DRAWINGS

FIG. 1 is a schematic sectional view of a solar cell module according to a first embodiment.

FIG. 2 is a schematic sectional view of a first protection member of the first embodiment.

FIG. 3 is a schematic plan view of the first protection member of the first embodiment.

FIG. 4 is a schematic plan view of solar cells and a wiring member of the first embodiment.

FIG. 5 is a schematic plan view of a portion V in FIG. 4.

FIG. 6 is a schematic sectional view taken along line VI-VI in FIG. 5.

FIG. 7 is a schematic sectional view of a first protection member of a second embodiment.

FIG. 8 is a schematic sectional view taken along line VIII-VIII in FIG. 7.

### DETAILED DESCRIPTION OF EMBODIMENTS

Preferred embodiments of the invention are described below. Note, however, that the embodiments given below are mere examples, and the invention is not limited to the embodiments below whatsoever.

Moreover, throughout the drawings referred to in the embodiments and the like, members having substantially the same functions are denoted by the same reference numerals. In addition, the drawings referred to in the embodiments and the like are schematically drawn, and the dimensions, ratios, and the like of objects depicted in the drawings may differ from actual values. Moreover, the dimensions, ratios, and the like of objects may differ from one drawing to another. Specific dimensions, ratios, and the like of objects should be determined based on the following description.

### First Embodiment

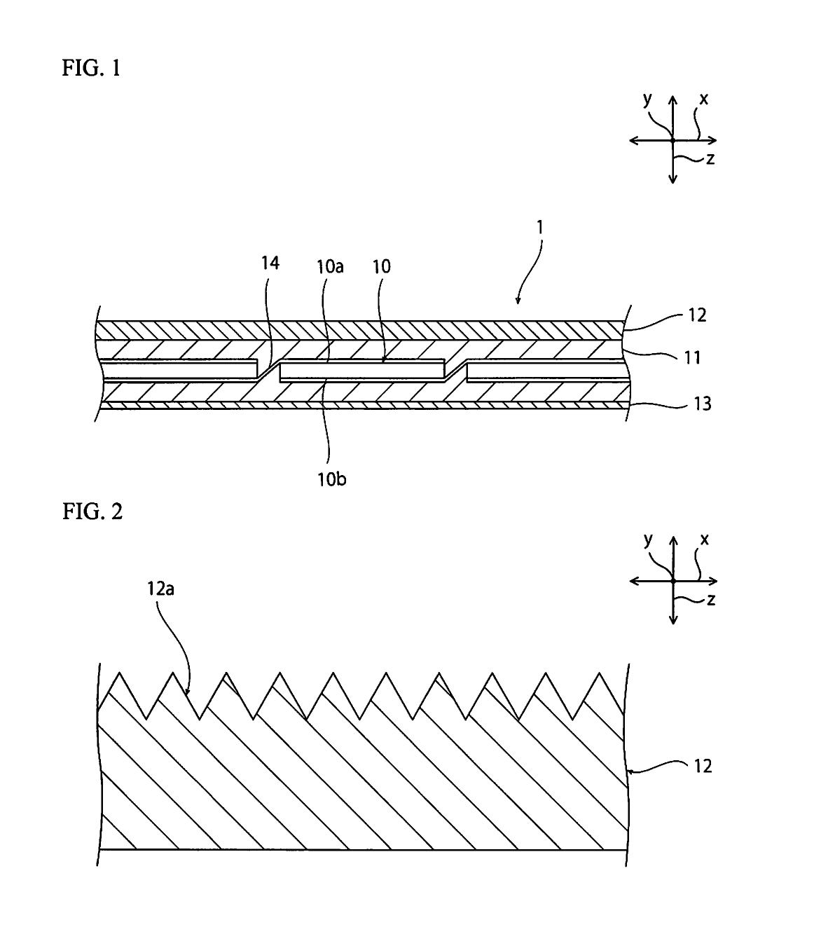

As illustrated in FIG. 1, solar cell module 1 includes solar cells 10. The solar cells 10 are electrically connected to one another with wiring members 14. Each solar cell 10 has light-receiving surface 10a and back surface 10b. Herein, light-receiving surface 10a is one of two principal surfaces of the solar cell 10 and receives a relatively large amount of light, and back surface 10b is the other one of the principal surfaces and receives a relatively small amount of light. Solar cell 10 may be a solar cell having a back contact structure which has a first electrode (s) and a second electrode (s) on back surface 10b, or a solar cell having the first electrode (s) on light-receiving surface 10a and the second electrode(s) on back surface 10b. In the following description, an x-axis direction is a direction in which solar cells 10 connected with wiring members 14 are arranged, and a y-axis direction is a direction which is orthogonal to the x-axis direction, such that the x-axis and the y-axis defines a plane (a x-y plane) parallel to light-receiving surface 10a. In addition, a z-axis direction is a direction orthogonal to the x-y plane and along the thickness direction of solar cell module 1.

First protection member 12 is placed on the light-receiving-surface 10a side of solar cells 10. Second protection member 13 is provided on the back-surface 10b side of solar cells 10. Sealing material 11 is provided between first protection member 12 and second protection member 13 to seal solar cells 10 therein. Sealing material 11 maybe made of, for example, a crosslinkable resin or a non-crosslinkable resin. Sealing material 11 can be made of an ethylene-vinyl acetate (EVA) copolymer, polyolefin, or the like. First protection member 12 can be made of, for example, a translucent or transparent member such as a glass plate, a ceramic plate, or a resin plate. Second protection member 13 can be made of, for example, a glass plate, a ceramic plate, a resin plate, a resin sheet, a resin sheet containing a metal layer, or the like.

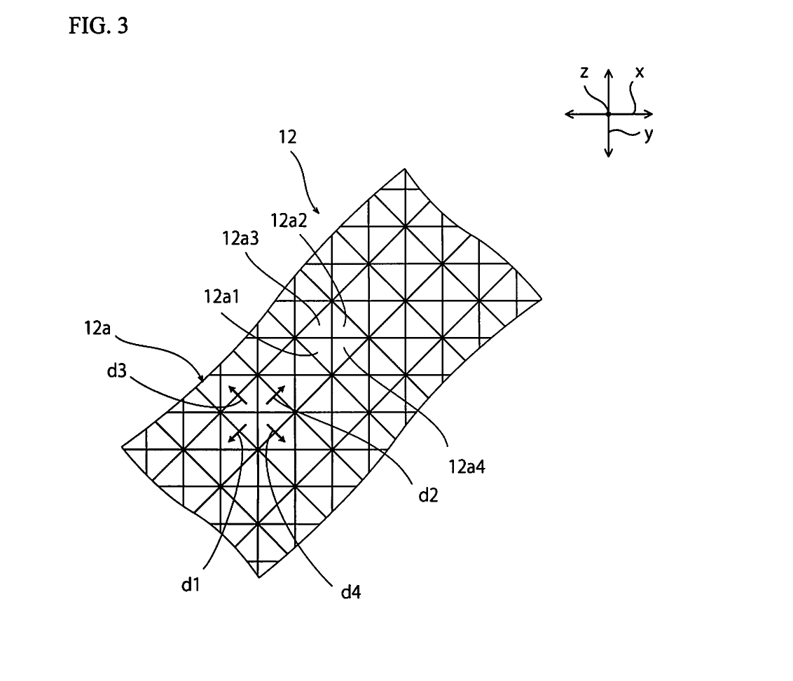

As illustrated in FIGS. 2 and 3, first protection member 12 has first texture 12a at its principal surface located at a side opposite from the solar cells 10. First texture 12a may have any shape. In this embodiment, first texture 12a is formed of square-pyramid bump portions arranged in matrix. A first angle defined as an angle of each of the surfaces of first texture 12a with respect to the principal surface of first protection member 12 is preferably 30° to 80°, and more preferably 40° to 70°. Each bump portion of first texture 12a has first face 12a1, second face 12a2, third face 12a3, and fourth face 12a4. Specifically, in a plan view (seeing the x-y plane in the z-axis direction), a normal to first face 12a1 is oriented in first direction d1, a normal to second face 12b2 is oriented in second direction d2, a normal to third face 12c3 is oriented in third direction d3, and a normal to fourth face 12d4 is oriented in fourth direction d4. An x-y plane component of first direction dl and that of second direction d2 are parallel to each other and different from each other by 180°. An x-y plane component of first direction d3 and that of second direction d4 are parallel to each other and different from each other by 180°. The x-y plane components of first and second directions d1 and d2 and those of the x-y plane components of third and fourth directions d3 and d4 are different from each other by 180°. First to fourth directions d1 to d4 are each oblique to the x-axis direction and to the y-axis direction in the plan view. Note that the “square pyramid” herein includes a square pyramid having a shape whose corner and/or redge lines are rounded.

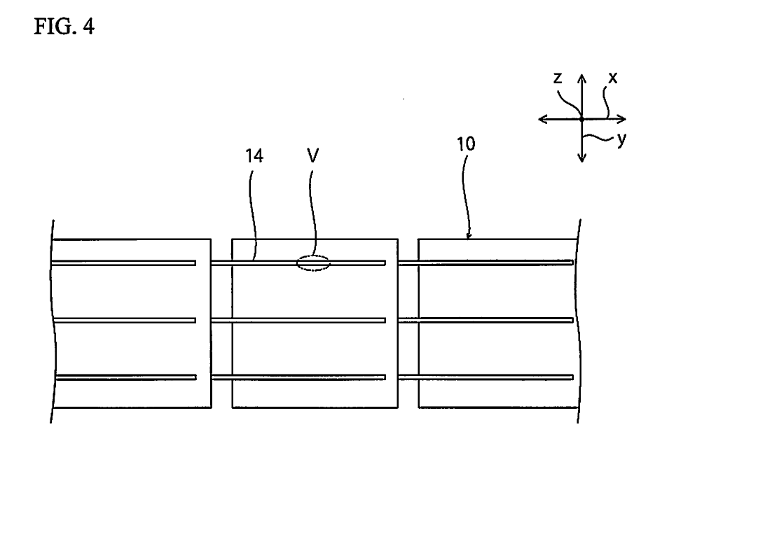

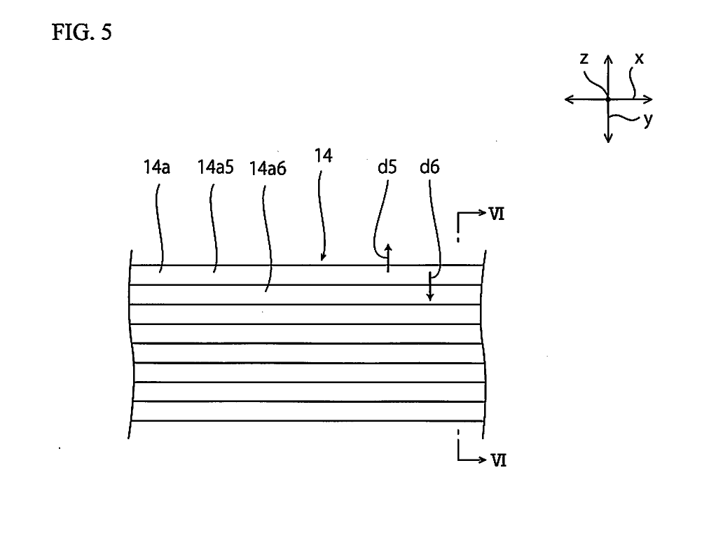

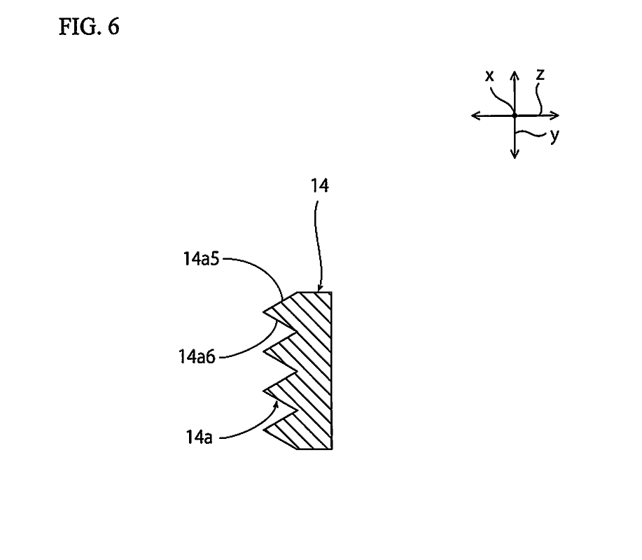

As illustrated in FIG. 4, wiring members 14 each have a long and thin shape extending in the x-axis direction. As illustrated in FIGS. 5 and 6, wiring member 14 has second texture 14a at its surface on the first protection member 12 side. Second texture 14a may have any shape. In this embodiment, second texture 14a is formed of at least one linear bump portion extending in the x-axis direction and having a triangle cross section. A second angle defined as an angle of each of reflective surfaces of the linear bump portion of wiring member 14 with respect to light-receiving surface 10a of solar cell 10 to which the wiring member 14 is fixed is preferably 20° to 40°, and more preferably 25° to 30°. The linear bump portion of second texture 14a has fifth face 14a5 and sixth face 14a6. Specifically, in a plan view, a normal to fifth face 14a5 is oriented in fifth direction d5, and a normal to sixth face 14a6 is oriented in sixth direction d6. An x-y plane component of fifth direction d5 and that of sixth direction d6 are parallel to each other and different from each other by 180°. An x-y plane component of fifth and sixth directions d5 and d6 are each parallel to the y-axis direction in the plan view. Note that the “triangle” herein includes a triangle having a shape whose corner is rounded.

As described above, in solar cell module 1, first protection member 12 is provided with first texture 12a at its principal surface located opposite from solar cells 10. Thus, the amount of light reflected by that principal surface of first protection member 12 can be reduced, and this can increase the amount of light entering solar cell module 1, and in turn, improve light-receiving efficiency of solar cells 10. For this reason, excellent output characteristics can be attained.

For example, suppose a case where a linear bump portion extending in the same direction as the linear bump portion provided on the surface of a wiring member is provided on the surface of a first protection member. In this case, angles between surfaces of the linear bump portion of the first protection member and reflective surfaces of the linear bump portion of the wiring member are reduced such that those surfaces are almost parallel to each other. As a result, light which has transmitted through the first protection member and been reflected by the reflective surface of the wiring member transmits through the first protection member again, resulting in that sufficient light cannot be encapsulated in solar cell module 1. In contrast, in solar cell module 1, first texture 12a and second texture 14a are provided such that, in the plan view (the X-Y plane view), the x-y plane components of directions d1 to d4, which are the normals to first to fourth faces 12a1 to 12a4 of first texture 12a, respectively, are different from the x-y plane components of directions d5 and d6, which are the normals to fifth and sixth faces 14a5 and 14a6 of second texture 14a, respectively. For this reason, light which has transmitted through first protection member 12 and been reflected by the reflective surface of wiring member 14 is reflected at a high rate again by first texture 12a of first protection member 12. Thus, light reflected by wiring members 14 can be encapsulated more in solar cell module 1. Hence, excellent output characteristics can be attained.

In order to attain the excellent output characteristics, angles of directions d1 to d4 with respect to directions d5 and d6 in the plan view are preferably 30° to 60°, and more preferably 40° to 50°.

Another preferred embodiment of the invention is described below. In the following description, members having substantially the same functions as those in the first embodiment above are denoted by common reference numerals, and are not described again here. FIGS. 1, 2, 4 to 6 are referred to in the second embodiment as they are in the first embodiment.

### Second Embodiment

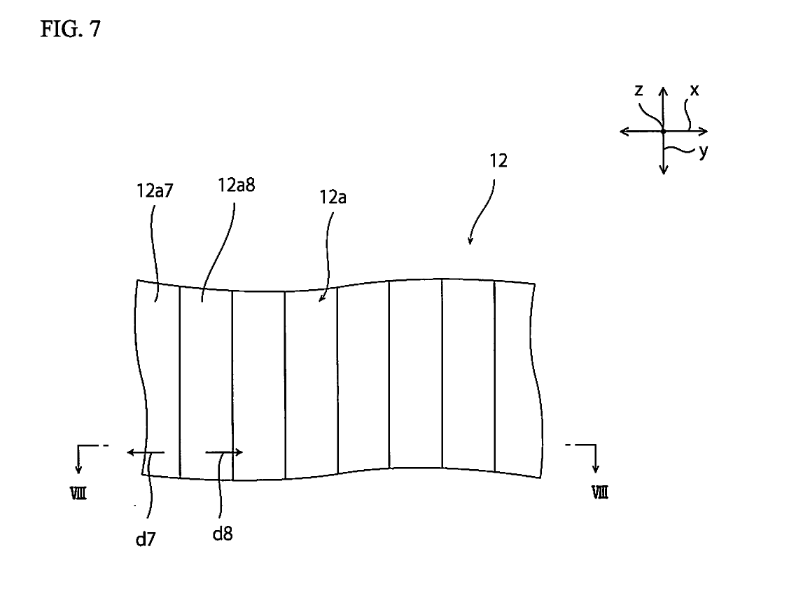

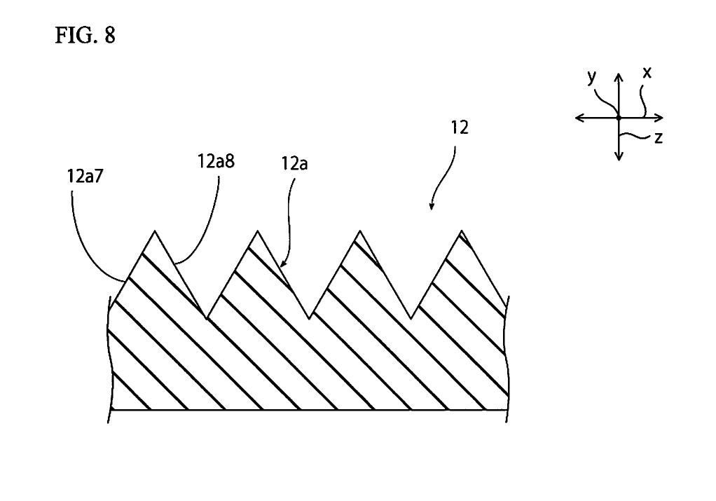

In the second embodiment, as illustrated in FIG. 7, first texture 12a is, like second texture 14a, formed of linear bump portions each having a triangle cross section. In first texture 12a, a third angle which is an angle of each of the surfaces of first texture 12a with respect to the principal surface of first protection member 12 is preferably 30° to 80°, and more preferably 40° to 70°. First texture 12a has seventh face 12a7 whose normal is oriented in seventh direction d7 and eighth face 12a8 whose normal is oriented in eighth direction d8. An x-y plane component of seventh direction d7 and that of eighth direction d8 are parallel to each other and different from each other by 180°. The x-y plane component of each of seventh and eighth directions d7 and d8 extend in the y-axis direction. Thus, in this second embodiment, in the plan view (the x-y plane view), directions d7 and d8 which are normals to the faces of each linear bump portion of first texture 12a are different from directions d5 and d6 which are normals to the faces of each linear bump portion of second texture 14a. As in the first embodiment, light reflected by the surface of wiring members 14 is reflected at a high rate by first texture 12a, and therefore can be encapsulated in solar cell module 1. Thus, excellent output characteristics can be attained.

When both first texture 12a and second texture 14a are formed of linear bump portions each having a triangle cross section as in the second embodiment, angles between directions d7, d8 and directions d5, d6 are preferably 70° to 90°, and more preferably 80° to 90°.

### Comparative Example 1

A solar cell module having substantially the same configuration as that of the first embodiment except that it does not have the first texture on the principal surface of its first protection member is fabricated such that second angles of reflective surfaces of a linear bump portion of a wiring member with respect to a light-receiving surface of a solar cell to which the wiring member is fixed are 30°. Then, output of this solar cell module is measured.

### Comparative Example 2

A solar cell module having substantially the same configuration as that of the first embodiment is fabricated, except that the normals to the first and second faces are oriented in the x-axis direction, and the normals to the third and fourth faces are oriented in the y-axis direction. Then, output of this solar cell module is measured. The second angles of the linear bump portion of the wiring member are set to 30° as in Comparative Example 1. The first angles are set to 60°.

### Example 1

A solar cell module having substantially the same configuration as that of the first embodiment is fabricated, and output thereof is measured. The second angle are set to 30° as in Comparative Examples 1 and 2, and the first angle are set to 60° as in Comparative Example 2. Angles of the first to forth directions with respect to the fifth and sixth directions are set to 45°.

### Example 2

A solar cell module having substantially the same configuration as that of the second embodiment is fabricated, and output thereof is measured. The second angles are set to 30° as in Comparative Examples 1 and 2 and Example 1, and the first angles of the linear bump portion forming the first texture are set to 60°. Angles of the seventh and eighth directions with respect to the fifth and sixth directions are set to 90°.

Tables 1 to 3 show output of the solar cell modules fabricated in Comparative Examples 1 and 2 and Examples 1 and 2, which output is observed when they are each irradiated with light at its light-receiving surface in the z-axis direction. The output values shown in Tables 1 to 3 are values normalized to output of Comparative Example 1 which is set to 100.

TABLE 1

| | | Angles between first | |
|---|---|---|---|
| | | to fourth directions | |
| | | and fifth and sixth | Output |
| | | directions in a plan | (normalized |
| | First texture | view (°) | value) |
| Comparative | Not provided | | 100 |
| Example 1 | | | |
| Comparative | Provided | 0° or 90° | 103.4 |
| Example 2 | (square | | |
| | pyramid) | | |

TABLE 2

| | | Angles between first | |
|---|---|---|---|
| | | to fourth directions | |
| | | and fifth and sixth | Output |
| | | directions in a plan | (normalized |
| | First texture | view (°) | value) |
| Comparative | Not provided | | 100 |
| Example 1 | | | |
| Example 1 | Provided | 45° | 103.7 |
| | (square | | |
| | pyramid) | | |

TABLE 3

| | | Angles between | |
|---|---|---|---|
| | | seventh and eighth | |
| | | directions and fifth | Output |
| | | and sixth directions | (normalized |
| | First texture | in a plan view (°) | value) |
| Comparative | Not provided | | 100 |
| Example 1 | | | |
| Example 2 | Provided | 90° | 104.3 |
| | (linear bump | | |
| | portion) | | |

As shown in Table 1, when the first texture formed of square-pyramid bump portions is provided such that the first and second directions or the third and fourth directions are parallel to the fifth and sixth directions in a plan view, output improves by 3.4%. In contrast, as shown in Table 2, when the first texture formed of square-pyramid bump portions is provided such that the first to fourth directions are oblique to the fifth and sixth directions in a plan view, output improves by 3.7%. Further, as shown in Table 3, when the first texture formed of linear bump portions is provided such that the seventh and eighth directions are oblique to the fifth and sixth directions in a plan view, output improves by 4.3%. It can be seen from the results above that output of a solar cell module can be improved when the solar cell module is provided with first texture and second texture such that, in a plan view, the extension directions of the normals to the faces constituting the first texture are different from the extension directions of the normals to the faces constituting the second texture.

Note that the angle of light entering the solar cell module differs depending on the installation place, method, and the like of the solar cell module. In addition, if the solar cell module generates power from solar light, the incident angle of the light changes. When the angle of light entering the solar cell module is not perpendicular to the solar cell module or not steady, it is preferable that the first angle in the first embodiment or the third angle in the second embodiment of the first protection member be set to various predetermined angles instead of a fixed predetermined angle. In other words, the square pyramids provided in the first embodiment or the linear bump portions provided in the second embodiment preferably have various heights in the z-axis direction.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell module comprising:
solar cells;
a wiring member electrically connecting the solar cells;
a first protection member provided on a light-receiving-surface side of the solar cells;
a second protection member provided on a back-surface side of the solar cells; and
a sealing material provided between the first protection member and the second protection member to seal the solar cells therein, wherein
the first protection member has a first texture on one of principal surfaces thereof that located opposite from the solar cells,
the wiring member has a second texture on one of principal surfaces thereof that faces the first protection member, and
the first texture and the second texture are provided such that, in a plan view, normals to surfaces of the first texture are not parallel to normals to surfaces of the second texture.

2. The solar cell module according to claim 1, wherein
the first texture comprises square-pyramid bump portions arranged in matrix,
the second texture comprises at least one linear bump portion having a triangular cross section, and
angles between the normals to the surfaces of the first texture and the normals to the surfaces of the second texture in the plan view are 40° to 50°.

3. The solar cell module according to claim 2, wherein
the first texture is formed such that first angles defined as angles of the surfaces of the first texture with respect to the other principal surface of the first protection member have two or more predetermined angles.

4. The solar cell module according to claim 2, wherein
first angles defined as angles of the surfaces of the first texture with respect to the other principal surface of the first protection member are 40° to 70°.

5. The solar cell module according to claim 1, wherein
the first texture and the second texture are each formed of at least one linear bump portion having a triangular cross section, and
angles between the normals to the surfaces of the first texture and the normals to the surfaces of the second texture in the plan view are 80° to 90°.

6. The solar cell module according to claim 5, wherein
the first texture is formed such that first angles defined as angles of the surfaces of the first texture with respect to the other principal surface of the first protection member have two or more predetermined angles.

7. The solar cell module according to claim 5, wherein
third angles defined as angles of the surfaces of the first texture with respect to the other principal surface of the first protection member are 40° to 70°.

8. The solar cell module according to claim 2, wherein second angles defined as angles of the surfaces of the second texture of the wiring member with respect to a light-receiving surface of a corresponding solar cell to which the wiring member is fixed are 20° to 40°.
